(19) United States
(12) Patent Application Publication
(10) Pub. No.: US 2002/0081760 A1
(43) Pub. Date: Jun. 27, 2002

(54) Individual detector performance in radiation detector arrays

(76) Inventor: Roger W. Whatmore, Bletchley (GB)

Correspondence Address: MOSER, PATTERSON & SHERIDAN, L.L.P., Suite 1500, 3040 Post Oak Blvd., Houston, TX, 77056, US

(21) Appl. No.: 10/005,883

(22) Filed: Dec. 3, 2001

(30) Foreign Application Priority Data
Dec. 4, 2000 (GB) 0029553.5

(51) Int. Cl. H01L 21/00; H01L 21/44; H01L 21/48; H01L 21/50; H01L 27/14; H01L 29/82; H01L 29/84; H01L 31/00

(52) U.S. Cl. 438/25; 438/24; 438/57; 438/66; 438/118; 257/414; 257/428

(57) ABSTRACT

The performance of individual detectors in pyroelectric detector arrays is improved by reducing the size of each detector as compared to the overall array size and providing each with a collection cavity which tapers from front aperture towards the detector itself.

This invention relates to a method for improving the performance of radiation (e.g. infrared) detector arrays such as uncooled pyroelectric detector arrays through the use of arrays of micromachined radiation collectors. Pyroelectric infra-red detectors have been used for many years for the detection of far infra-red radiation and the wavelength-independence of their response has led to their being used in a wide variety of applications, including people sensors, spectroscopy, fire & flame detection, environmental control etc. Arrays of pyroelectric detectors have received considerable attention over the last 15 years because of their potential for giving good quality thermal images without any requirement for cooling, unlike the photon detectors which need to be operated typically at 77K. The commercial versions of these arrays are mainly currently used in fire-fighting, police and military night-vision applications and these are typically manufactured using bulk ceramic materials which are lapped and polished to ca 30 μm thickness, laser micromachined to thermally isolate the individual elements (reticulated) and flip-chip bonded to a 2D silicon amplifier multiplexer chip. These employ arrays of thermal sensors bonded to complex mixed analogue-digital signal VLSI CMOS chips. Typical thermal imaging arrays are being made with 10K to 100K elements at pitches of between 100 and 40 μm. There is also a requirement for lower element count (few hundred to few thousand) arrays for systems aimed at a variety of markets ranging from people sensing to environmental monitoring and medical applications.

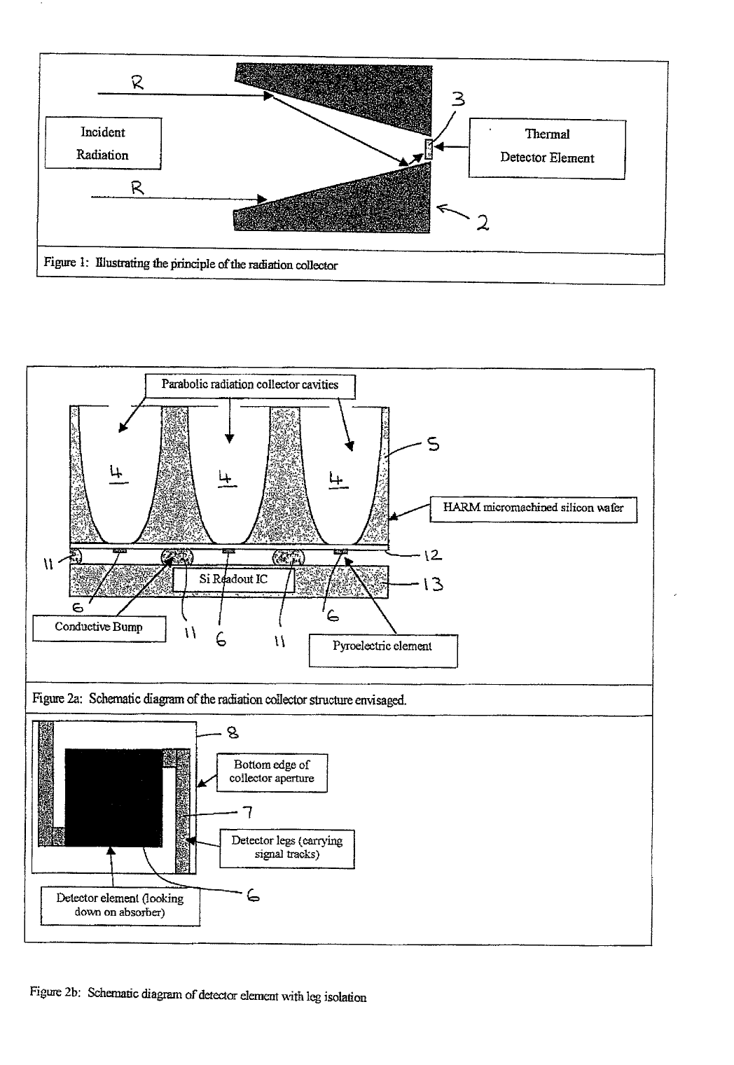

It is interesting to note that the specific detectivity (D^{*}) of well-designed individual pyroelectric detector elements is typically in the range 2.10⁸ to 5.10⁸ cmHz^{½}W⁻¹. However, there are major advantages to be gained in individual detector performance by reducing the area within a pixel (a single picture element area) occupied by the detector, while at the same time concentrating the radiation from the full pixel area into that reduced detector area. There are various means that have been postulated for doing this with individual thermal detectors, including antenna-coupling and the use of condensing horns or light pipes. The latter approach has some advantages in that it requires a single small detector at the collection point. The antenna coupling approach requires an array of detector elements within the overall collector area. An example of a collector horn cavity is shown schematically in FIG. 1. Radiation R entering the aperture 1 of the collector horn 2, which can be conical or profiled (e.g. parabolic) to improve the collection efficiency, is collected down onto a detector element 3 at its base by successive reflections at the horn surface. If the detector element 3 at the base of the horn is made using ferroelectric thin film technology, there can be a number of major advantages over the more-conventional type of discrete detector made from bulk ceramic. It can be well thermally isolated and very thin, giving small thermal mass. The small thickness allows the capacitance of the detector element to be maintained, keeping noise under control.

A first aspect of the present invention provides a method of fabricating a radiation detector array comprising the steps of:

a) providing,. on one face of a layer of material, an array of detector elements;

b) forming an array of cavities in the layer of material such that each detector is positioned at the base of a cavity; and

c) bonding the array of cavities and detectors to a silicon integrated circuit including a corresponding array of amplifiers and multiplex switches.

In principal, steps a) and b) can be reversed (see annexed claim 2) although the above is the presently preferred method. Other preferred features of the method of the invention are described in claims 3 to 9.

The invention also provides a radiation array as claimed in claim 10. Preferred features of the array are listed in claims 11 to 28.

An embodiment of the invention will now be described by way of example only and with reference to the accompanying drawings in which

FIG. 1 is a schematic cross sectional view of the detector having a conical radiation collection cavity;

FIG. 2a is a schematic cross sections view of the detector array according to the present invention;

FIG. 2b is a top plan view of one of the detector elements shown in FIG. 2a;

FIG. 2c is a top plan view of an alternative detector element suitable for the array of FIG. 2a;

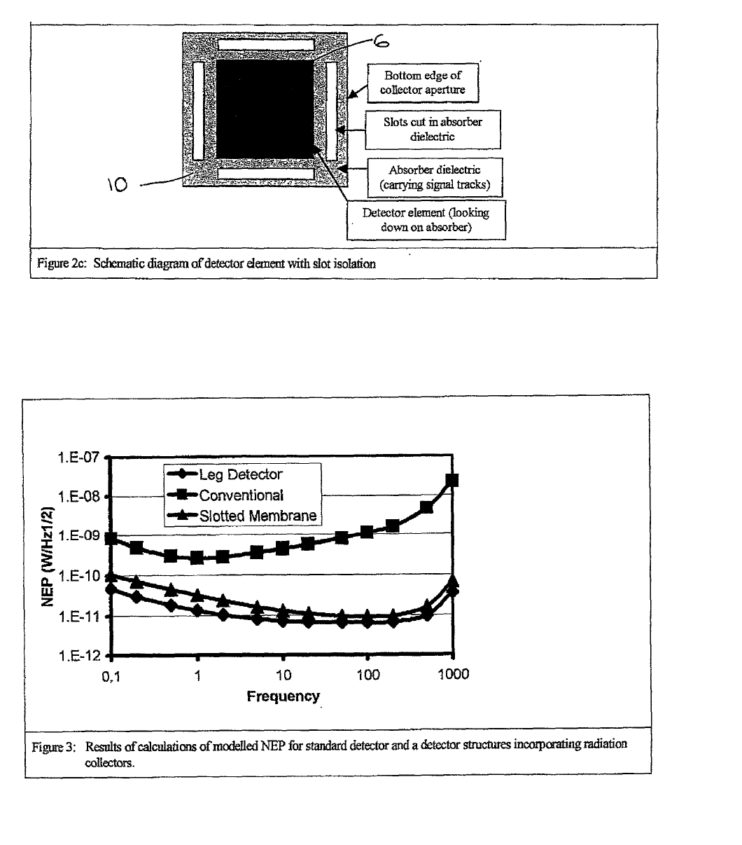

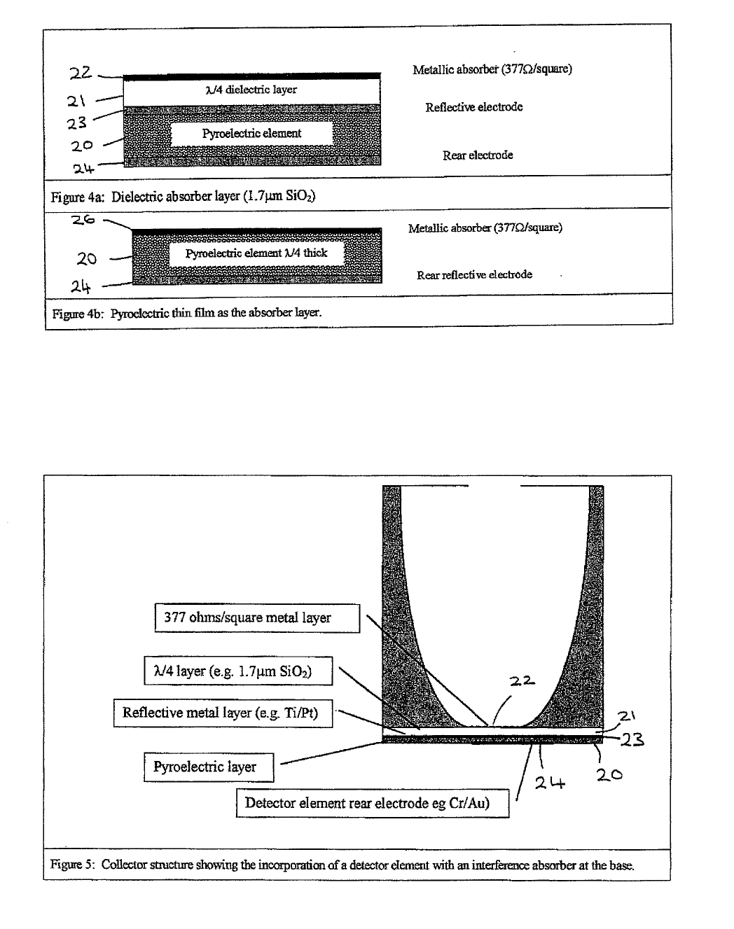

FIG. 3 is a graph of results of calculations of modified NEP for a standard detector and detector structures incorporating radiation collection cavities;

FIGS. 4a and 4b are cross section views of two detector elements suitable for use in the present invention;

FIG. 5 is an enlarged cross sectional view of a collector cavity structure showing the incorporation of a detector element with an interference absorber at the base;

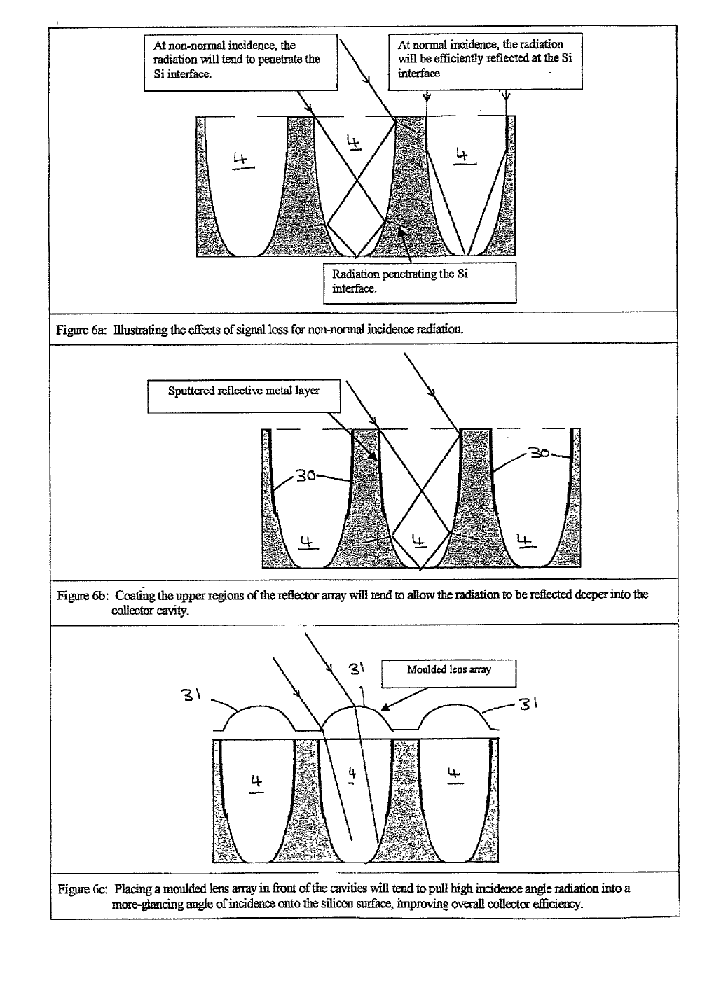

FIG. 6a is a cross section through a collector cavity array showing the paths of radiation through the cavities;

FIG. 6b is similar to FIG. 6a with the addition of metal layers on the cavity surfaces;

FIG. 6c is similar to 6b with the addition of a lens array; and

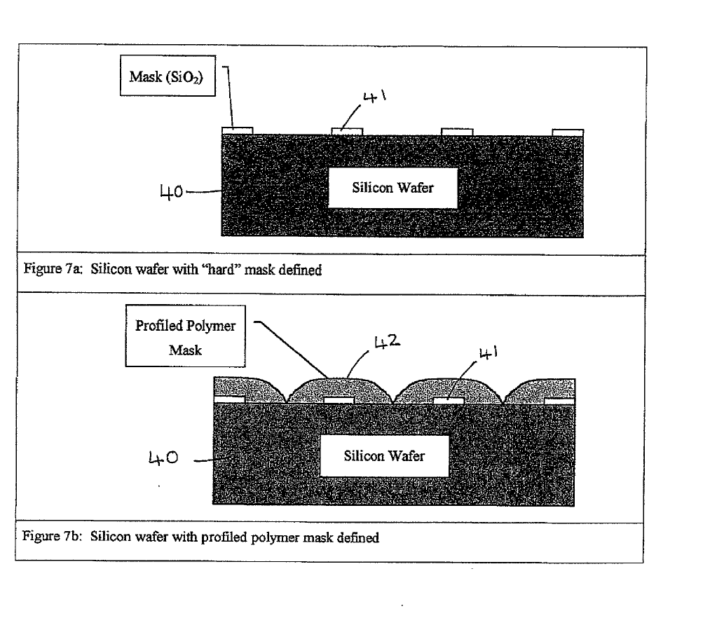

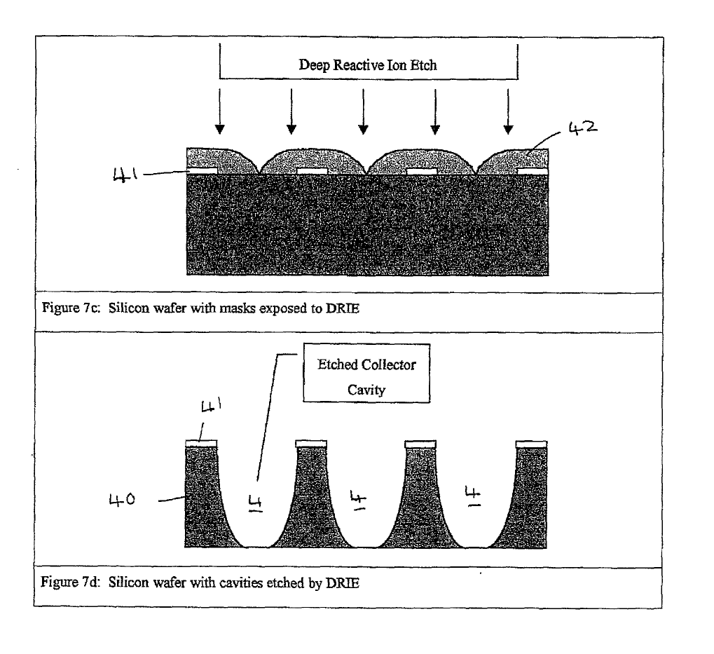

FIGS. 7a to 7d are a series of cross sectional views illustrating the manufacturing process.

### DESCRIPTION OF INVENTION

The preferred embodiment of the invention uses deep reactive ion etching of a silicon wafer in association with ferroelectric thin film technology to create a detector array plane consisting of a two dimensional array of parabolic radiation collectors with thin film pyroelectric detectors at their base. FIG. 2a shows a schematic diagram of the structure. The parabolic cavities 4 can be formed in a substrate 5 such as a silicon wafer by using a process such as Deep Reactive Ion Etching. A possible design of the detector element 6 is shown schematically in FIG. 2b. The legs 7 on the detector are intended to provide good thermal isolation for the element. The detector 6 is positioned just below the lower edge 8 of the cavity 4 which is square in this example. Other simpler designs such as slotted membranes 10 are also possible, see FIG. 2c. It is possible to model the radiometric characteristics of such a collector structure and compare it with those of the more conventional designs using bulk ceramic in which the radiation is collected over the full area of detector element, which is flip chip bonded to a silicon substrate. Conductive bumps 11 are provided to link each detector element 6 on the pyroelectric detector/collector array wafer 12 to individual amplifiers on the silicon chip 13. These conductive bumps can be made by several methods and from several materials, for example from evaporated solder, screen-printed silver loaded epoxy or electroplated gold.

FIG. 3 shows a plot of predicted noise equivalent power (NEP) obtained from a bump-bonded detector 500 microns square, using the standard pyroelectric properties available for a modified lead zirconate ceramic and the known noise properties of a particular read-out circuit. 90% absorption efficiency is assumed. The standard equations for pyroelectric device operation have been used. These can be found in Porter S.G. (1981), A brief guide to pyroelectric detectors, Ferroelectrics 33 193-206; and Whatmore R. W. (1986), Pyroelectric materials and devices, Rep. Prog. Phys. 49 1335-1386.

In comparison with this, we present the NEP curves from a detector structure using quite conservative collector parameters. We assume collection over a 450 micron aperture (on a 500 micron pitch) down onto a detector contained within a 100 micron aperture at its base. A collection efficiency of only 25% is assumed. Two detector designs have been modelled, one as in FIG. 2b, the other being a rather simpler design of a membrane detector with slots cut in it to reduce its thermal conductance (FIG. 2c). The details of the type of detector structure are showing in FIG. 4a. In both cases it is assumed that the detector consists of 1 micron thick layer 20 of PZT30/70 on a 1.7 micron thick SiO₂ membrane 21, coated with 377 ohms/sq. metal 22, that acts as an interference absorber. The SiO₂ layer acts as an interference absorber consisting of a /4 dielectric layer (=10 μm). A reflective electrode 23 is positioned between the PZT layer and SiO₂ membrane 21 and a rear electrode 24 lies on the back of the PZT layer 20. Alternatively, the dielectric in the absorber could be a 1.1 μm thick layer 20 of the ferroelectric itself (FIG. 4b) covered with a 377 ohms/sq. metal 26. This would provide a further improvement in thermal sensitivity and reduction in thermal conductance. The results for the NEP predictions for both detector designs are very encouraging (see FIG. 3). At least an order-of-magnitude improvement (reduction) in NEP is predicted. A higher collector efficiency would lead to a proportionate increase in performance. Alternative materials to use in the detector element would be lead scandium tantalate or a copolymer of polyvinylidene fluoride and trifluoroethylene (PVDF/TrFE) with between 55 and 85% polyvinylidene fluoride.

FIG. 5 is a more detailed schematic view showing the incorporation of a detector element with an interference absorber at its base. The structure of the detector element corresponds to that shown in FIG. 4a.

The use of radiation collectors such as this is well known in a variety of fields, including infra-red detection (especially at very long wavelengths) and sub-mm wave detection and solar collectors. However, the principle has never before been applied to arrays of thermal IR detectors. It is not necessary for the profile of the collector to be accurately parabolic. Indeed, conical collector horn profiles have been used effectively.

It is possible to provide for means by which the collection efficiency of the individual radiation collectors can be improved. In FIG. 6a we see one potential problem with the loss of collection efficiency due to only partial reflection at the collector walls. If the collectors are made out of silicon, then the reflection at the collector wall surface will be less than completely ideal. Radiation incident normal to the array plane should experience a high degree of reflection at the silicon surface because it is incident on a high refractive index material (n=3.49) at a glancing angle. As the angle of incidence increases, progressively more radiation will penetrate the silicon surface, effectively losing signal to the detector element. One possible way this effect could be ameliorated would be to coat the upper surface of the collector aperture with a metallic reflector layer by sputtering or thermal evaporation (see FIG. 6b) where the incidence angle of the metal arriving at the collector cavity 4 is at an angle to the top surface of the collector, the collector being rotated in the metal deposition system. It is well known that conical collectors suffer from a degradation in collection efficiency at high incident angles, simply from the geometry. A way to improve overall collector efficiency at high incident angles would be to partly or wholly fill the cavities with a transparent dielectric material of higher refractive index than air, or alternatively to include an array of lenses 31 at the collector aperture. These would be made out of a suitable IR transparent plastic —see FIG. 6c. In this case, the collector cavities could be wholly or partly filled with the same material as the lens array. If the detectors were pyroelectric detectors then any material filling the cavities would have to be kept out of physical contact with the detector element to avoid loss of thermal performance.

The thin film of the pyroelectric material and hence the pyroelectric element can be made by a range of techniques. Typically this would be made prior to the etching of the cavities 4 in the silicon wafer. In one method for doing this, the face of the wafer to bear the pyroelectric detectors is first coated with a layer of SiO₂ arranged to be a quarter wavelength thickness at the centre wavelength for the radiation of interest. In the case of 10 micron wavelength in air this will be about 1.71 μm thick in SiO₂. This is then coated with 50 nm of TiO₂ by a process such as reactive magnetron sputtering of titanium in a mixture of argon and oxygen. This is then coated by 50 nm of Ti and 100 to 150 nm of Pt, deposited by a process such as reactive magnetron sputtering from the respective metal targets in pure argon. The pyroelectric material can then be deposited on this platinum electrode, which also serves as the back reflector for the infra-red absorber. For example, if the pyroelectric material is to be a thin film of lead zirconate titanate, this can be deposited on the platinum by one of the well-known processes such as RF magnetron sputtering or chemical solution deposition. Alternatively, lead scandium tantalate can be similarly be deposited by one of these methods. Alternatively, PVDF/TrFE coatings can be deposited by spinning down a solution of said copolymer in methylethylketone, said layer being dried and annealed at ca 180° C. The back electrodes to the detectors can then be deposited on the pyroelectric material by means of evaporation. These electrodes can be patterned by one of the techniques well known to those skilled in the art of integrated circuit manufacture. The pyroelectric elements such as lead zirconate titanate need to be either electrically poled by the application of a strong electric field (greater than the coercive field) prior to use or alternatively for materials with low Curie temperatures (such as lead scandium tantalate) means needs to be provided in the electronic readout circuit for applying a constant DC voltage during use.

The fabrication of the collector arrays can be accomplished by a range of potential techniques and one is described below. The process generally known as deep reactive ion etching (DRIE) is well known for its ability to etch deep holes into silicon wafers. It is also well known that photoresists can be used to provide etch masks for this process, although these are themselves slightly etched during the DRIE process. One possible way to manufacture the array collector cavities is described as follows:

1. Place on the front of the silicon wafer 40 into which the cavities 4 are to be etched, a hard mask 41 of a material which is only etched very slowly in the DRIE process, SiO₂ or Si₃N₄ for example. This is shown schematically in FIG. 7a.

2. Define over the surface with the hard mask 42 a photoresist mask made with a thickness profile defined using a “grey-scale” mask exposure. The profile on this mask to be determined by the profile that is required in the final collector cavities. This is shown schematically in FIG. 7b.

3. Expose the surface with the masks 41, 42 to a DRIE. This is shown schematically in FIG. 7c.

4. The DRIE will have the effect of eroding the polymer mask at a slow but well defined rate and this will transfer a pattern into the silicon wafer, the profile of which will be defined by the profile in the original polymer mask. Eventually the required collector profile is defined in the silicon wafer as shown schematically in FIG. 7d.

1. A method of fabricating a radiation detector array comprising the steps of:
a) providing on one face of a layer of material, an array of detector elements;
b) forming an array of cavities in the layer of material such that each detector is positioned at the base of a cavity; and
c) bonding the array of cavities and detectors to a silicon integrated circuit including a corresponding array of amplifiers and multiplex switches.

2. A method as claimed in claim 1 in which the layer of material is a silicon wafer and the cavities are formed by etching the wafer.

3. A method as claimed in claim 2, in which the etching process is deep reactive ion etching.

4. A method as claimed in claim 1 in which a profiled polymer mask is used to define the array of cavities.

5. A method as claimed in claim 1 comprising the further step of at least partially coating the cavities with metal.

6. A method as claimed in claim 5, in which the metal is sputtered onto the cavities.

7. A method as claimed in claim 5, in which the metal is evaporated onto the cavities.

8. A method as claimed in claim 1 including the further step of wholly or partially filling the cavities with dielectric material of refractive index higher than air.

9. A method of fabricating a radiation detector array comprising the steps of:
a) forming an array of cavities in a layer of material;
b) providing, on one face of the material, an array of detector elements such that one element is positioned at the base of each cavity; and
c) bonding the array of cavities and detectors to a silicon integrated circuit including a corresponding array of amplifiers and multiplex switches.

10. A method as claimed in claim 9 in which the layer of material is a silicon wafer and the cavities are formed by etching the wafer.

11. A method as claimed in claim 10, in which the etching process is deep reactive ion etching.

12. A method as claimed in claim 9 in which a profiled polymer mask is used to define the array of cavities.

13. A method as claimed in claim 9 comprising the further step of at least partially coating the cavities with metal.

14. A method as claimed in claim 13, in which the metal is sputtered onto the cavities.

15. A method as claimed in claim 13, in which the metal is evaporated onto the cavities.

16. A method as claimed in claim 9 including the further step of wholly or partially filling the cavities with dielectric material of refractive index higher than air.

17. A radiation detector array comprising an array of radiation collector cavities formed in a layer of material, each cavity having a detector element at its base, wherein the array of cavities and detectors is bonded to a silicon integrated circuit including a corresponding array of amplifiers and multiplex switches.

18. An array as claimed in claim 17, in which the detector elements are infrared detector elements.

19. An array as claimed in claim 17 in which the cavities are shaped so as to have a gradually reducing cross sectional area from their openings towards their bases.

20. An array as claimed in claim 19, in which the cavities are conical.

21. An array as claimed in claim 19, in which the inner surfaces of the cavities are parabolic in shape.

22. An array as claimed in claim 21, in which the detectors are positioned at the foci of the parabolas.

23. An array as claimed in claim 17 wherein the pyroelectric detectors are made from a thin film of a material that is substantially lead zirconate titanate.

24. An array as claimed in claim 17 wherein the detectors are made from a thin film of a material that is substantially lead scandium tantalate.

25. An array as claimed in claim 17 wherein the detectors are made from a thin film of a material that is substantially a copolymer of polyvinylidene fluoride and trifluoroethylene.

26. An array as claimed in claim 17, wherein the array is bonded using conductive bumps are made of silver loaded epoxy.

27. An array as claimed in claim 17 wherein the array is bonded using conductive bumps made of solder.

28. An array as claimed in claim 17 wherein the array is bonding using conductive bumps made of electroplated gold.

29. An array as claimed in claim 17, wherein the cavities are at least partially coated with metal.

30. An array as claimed in claim 17 wherein the cavities are each provided with a lens to improve the angular collection efficiency.

31. An array as claimed in claim 17 wherein the cavities are wholly or partially filled with a dielectric material of higher refractive index than air.

32. An array as claimed in claim 30 wherein the cavities are wholly or partially filled with a dielectric material of higher refractive index than air and the material wholly or partially filling the cavities is the same as the lens material.

33. An array as claimed in claim 17 wherein the detector elements are each provided with a thin film absorber.

34. An array as claimed in claim 17, wherein the absorber comprises a thin film of silicon dioxide coated with a thin layer of metal.

35. An array as claimed in claim 1 in which the detector elements are pyroelectric detector elements.
